(19) United States
(12) Patent Application Publication
(10) Pub. No.: US 2013/0027879 A1
(43) Pub. Date: Jan. 31, 2013

(54) METHOD FOR REGULATING A COOLING SYSTEM

(71) Applicants: Helmut Saal, Reiferscheid (DE); Michael Nicolai, Allertshausen (DE)

(72) Inventors: Helmut Saal, Reiferscheid (DE); Michael Nicolai, Allertshausen (DE)

(73) Assignee: RITTAL GMBH & CO. KG, Herborn (DE)

(21) Appl. No.: 13/261,376

(22) PCT Filed: Jan. 12, 2011
(86) PCT No.: PCT/EP2011/050328

§ 371 Date: Aug. 15, 2012

(30) Foreign Application Priority Data
Jan. 21, 2010 (DE) 10 2010 005 192.6

(51) Int. Cl. H05K 7/20

(52) U.S. Cl. 361/695; 361/688; 361/690

(57) ABSTRACT

The invention relates to a method for regulating a cooling system for cooling electrical built-in devices housed in control panels or racks by means of cooling units assigned thereto, through which a liquid cooling medium, cooled down from a return temperature to a flow temperature by means of a cooling apparatus of the cooling system flows, wherein a cooling power for cooling the built-in devices can be regulated by a primary reference variable according to specification. Energy-efficient cooling is achieved in that the flow temperature is variably adjusted according to a cooling power demand in the region of the built-in devices, wherein the primary reference variable is formed from the cooling power demand in the region of the built-in devices.

The invention relates to a method for regulating a cooling system for cooling electrical built-in devices housed in control cabinets or racks by means of cooling units assigned thereto, through which a liquid cooling medium, cooled down from a return temperature to a flow temperature by means of a cooling apparatus of the cooling system, flows, wherein a cooling power for cooling the built-in devices can be regulated by a primary reference variable according to specification, as well as an arrangement for performing the method.

Such a regulation method is disclosed in EP 1 604 262 B1 wherein a cooling liquid is cooled down to a predefined temperature in a back-flow cooling apparatus. Cooling units flown by the cooling liquid are associated with individual electrical built-in devices. Often, control cabinets or racks are densely packed with built-in devices, in particular servers, so that a high cooling power demand exists for cooling the built-in devices which requires high expenditure of cooling energy. For energy saving, a most efficient cooling concept is aimed at.

DE 10 2006 051 904 A1 shows a cooling system comprising cooling units for blowing cooling air in the area of built-in devices of a control cabinet or rack, wherein the cooling units are flown through by cooling water. Regulation of the flow temperature of the cooling water occurs by means of a control device. The flow rate of a pump means may be regulated in accordance to the return and/or flow temperature of the cooling water to provide the requisite amount of cooling water and cooling power. The cooling system includes an external cooling circuit. Also with such an arrangement of the cooling system, a high cooling power for electrical built-in devices, such as e.g. servers, may be provided, wherein likewise a respective energy expenditure is necessary.

Another air-conditioning system for control cabinets having different cooling components and a control apparatus is described in DE 106 15 469 C2. Further, DE 297 24 561 U1 and DE 101 08 599 C2 disclose air-conditioning systems or cooling systems, respectively, for electrical built-in devices installed in control cabinets or racks as well as control and regulation concepts.

DE 603 05 436 T2 discloses a method and a system for cooling a room including a plurality of computer systems, wherein a row of vaporization units is present and temperatures are detected at one or more positions in the room to perform temperature control of the air. Here, an energy efficient cooling is also difficult.

DE 100 29 664 A1 shows an air conditioning system for central installation locations of telecommunications and radio technology, wherein the number of coolers is determined according to n+1 and a free-cooling operation is mentioned.

It is the object of the invention to provide a method for regulating a cooling system for cooling electrical built-in devices housed in control cabinets or racks as well as a respective arrangement to achieve a most-energy efficient, environmentally friendly cooling.

This object is solved by the features of claim 1. Herein, it is provided that the flow temperature is variably adjusted according to a cooling power demand in the region of the built-in devices, wherein the primary reference variable is derived from the cooling power demand in the region of the built-in devices.

By this approach, a provision of cooling power precisely adaptable to the respective cooling power demand is successful, wherein also an optimized adaption to external conditions is allowed. For example, in server cabinets, the server air supply temperature may be maintained constantly at a value desired by a user. That value or the primary reference variable, respectively, may be dynamically adjusted in accordance with a state of the system. The cooling medium sources may be used most environmentally friendly. For a quick reaction to cooling demands, e.g. a cooling medium volume may still be varied by controlling pumps having variable pumping power. Variable adaptive adjustment of the flow temperature finally results in an efficient energy use. A cooling unit may respectively be associated with one or more built-in devices.

An advantageous embodiment of the method consists in that the cooling apparatus comprises a back-flow cooling apparatus for cooling the cooling medium at least partly and/or at least temporarily.

An advantageous performing of the regulation method is further achieved in that the primary reference variable is determined from a supply air temperature of supply air in the region of the built-in devices, for example a 19″ installation level, wherein the supply air temperature is maintained at a predefined level by the cooling system.

For efficient cooling, advantageous embodiments consist in that the cooling system comprises several cooling units having fans which produce the supply air and that the predefined or produced supply air temperature values of all cooling units are compared to determine the smallest or, optionally, the same value, and the supply temperature is based on the smallest supply air temperature value, thus determining the primary reference value and adjusting the water flow temperature.

A cooling-effective regulation concept consists in that within the control system each cooling unit is seen as having an active pre-set value, that a comparison of the temperature difference between pre-set value and actual value of each cooling unit is made and that a control deviation for control is derived from the presently largest temperature difference of the cooling unit.

Good possibilities for adaption to different cooling requirements are further achieved in that a PID control is performed.

For advantageously regulating the cooling, those features further contribute that in a PID control a temporal variation of the control deviation is considered as D part of the control deviation, and, if the temporal variation exceeds a pre-defined threshold, the flow temperature is adjusted. Additionally, the regulation is performed by altering the pumping power in accordance with the power demand.

A stable regulation with good adjustability is supported in that the flow temperature is adjusted by altering a pre-set value of the flow temperature and the flow temperature is adjusted to the altered pre-set value of the flow temperature.

For environmentally-friendly use of energy those measures contribute that the cooling of the cooling medium is provided at least temporarily, partly or completely by means of a free-cooling device or an earth cooling device or an absorption cooling device.

The regulation concept is favored in that a free-cooling pre-set value is calculated from the pre-set value of the flow temperature minus a known temperature difference of the free-cooling device and further in that the free-cooling pre-set value is adaptively adjusted in response to cooling requirements.

A further advantageous embodiment of the method consists in that the primary reference value is determined according to a most energy-efficient cooling possible of the built-in devices, in particular servers, wherein the power dissipation of the built-in devices in the range of allowable operating temperatures is calculated in accordance with a most energy efficient operation possible of the system as a whole, including the cooling system. By these measures, even the operation of the built-in devices, for example servers, is included into the energy balance of the system as a whole including the cooling system, and the allowed temperature range is used for safe operation of the built-in devices. For example server fans which are inherently installed in the server housing may be operated with lower of higher power in conjunction with the cooling power provided by the cooling system, i.e. cooling air supplied by the cooling system, providing that the total energy balance is optimized.

Namely, under specific conditions, an increased power consumption of the servers at higher supply air temperature by the cooling system may count less than the energy saved in the region of the cooling system. If, however, cooling air may be provided favorably by the free-cooling device, e.g. at low environment temperature, it may be better to cool servers or built-in devices, respectively, stronger so that they may be operated at a least possible power dissipation.

For the arrangement, advantageous variants of embodiment consist in that additionally a free-cooling device is provided and that the control apparatus is for performing the method of any of claims 8 to 10.

The invention is further explained below by exemplary embodiments with reference to the drawings. It is shown in:

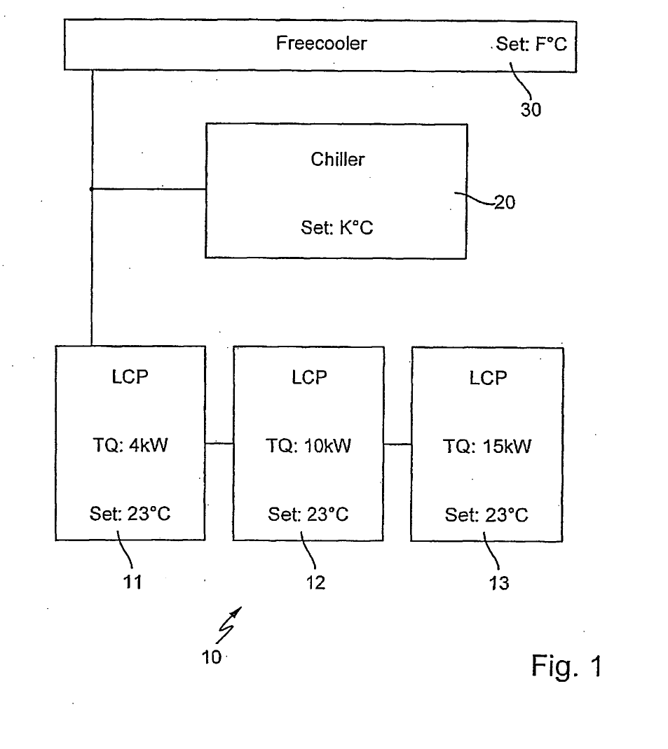

FIG. 1 a schematic illustration of a cooling system with back-flow cooling apparatus, free-cooling device and several cooling units,

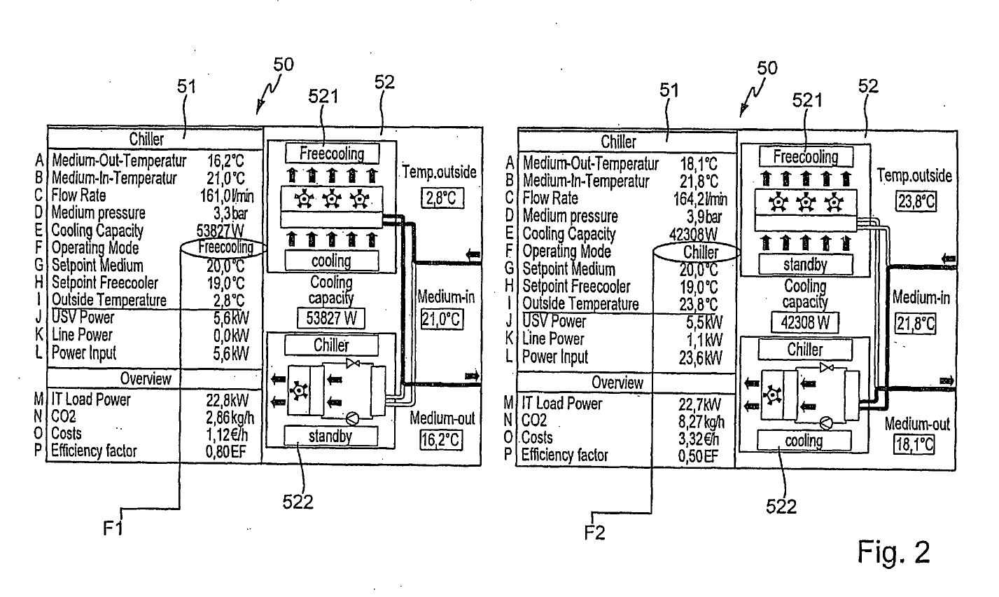

FIG. 2 an illustration of the cooling system by means of a display having alphanumeric part and graphic part,

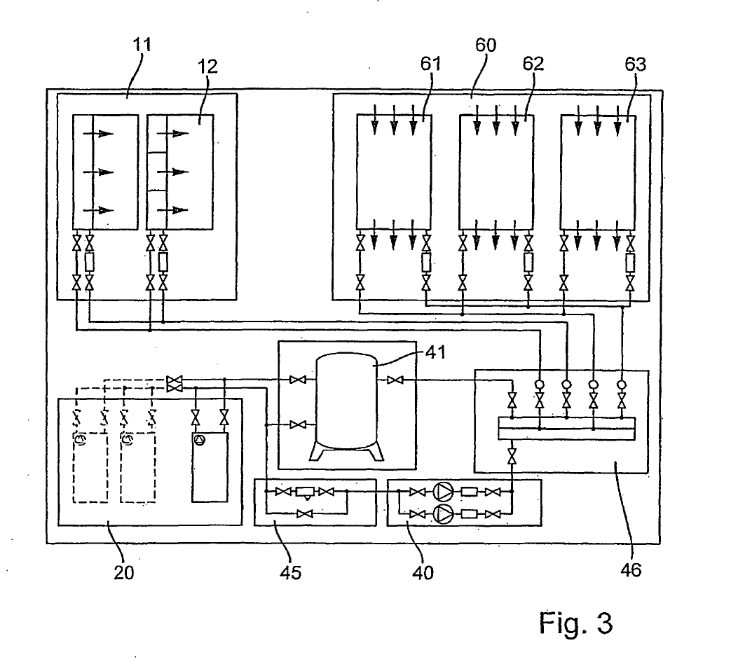

FIG. 3 a cooling system having cooling units and different components of a cooling apparatus,

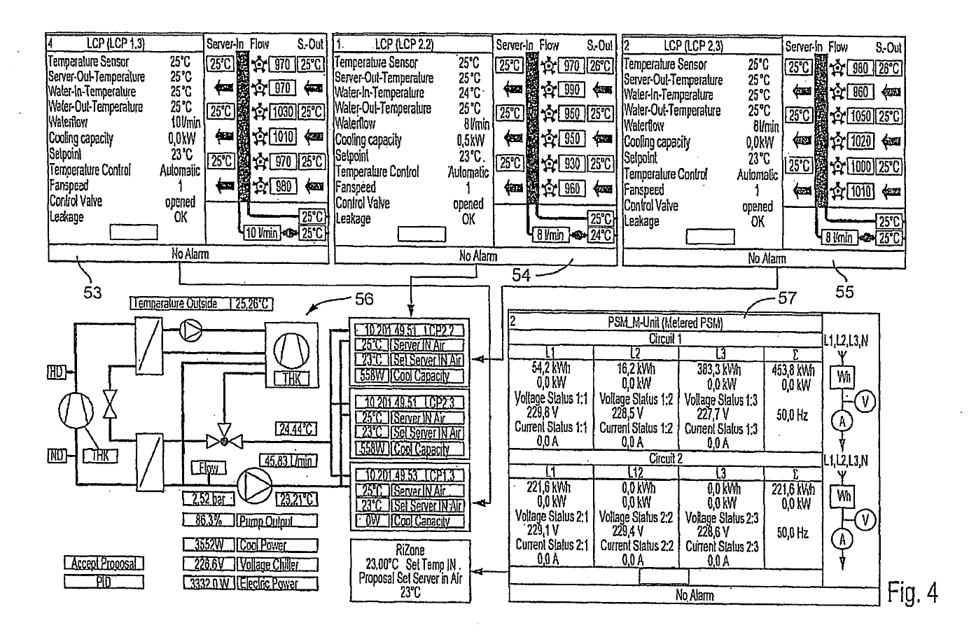

FIG. 4 a further illustration of the cooling apparatus by means of the display having alphanumeric part and graphic part,

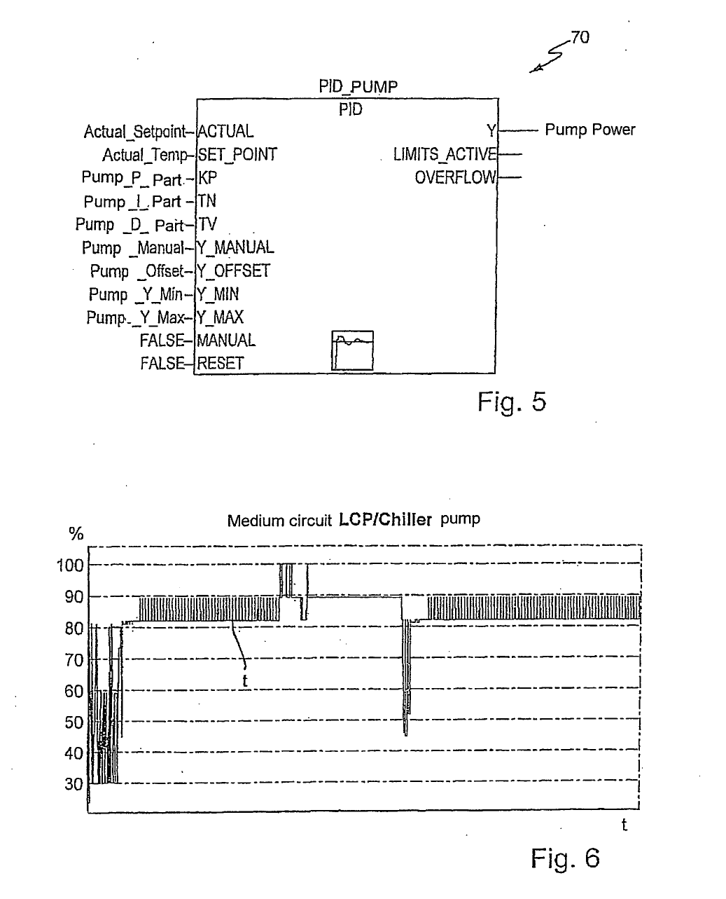

FIG. 5 a control unit of the cooling system,

FIG. 6 a plot of the pumping power of the back-flow cooling apparatus in percentages versus time,

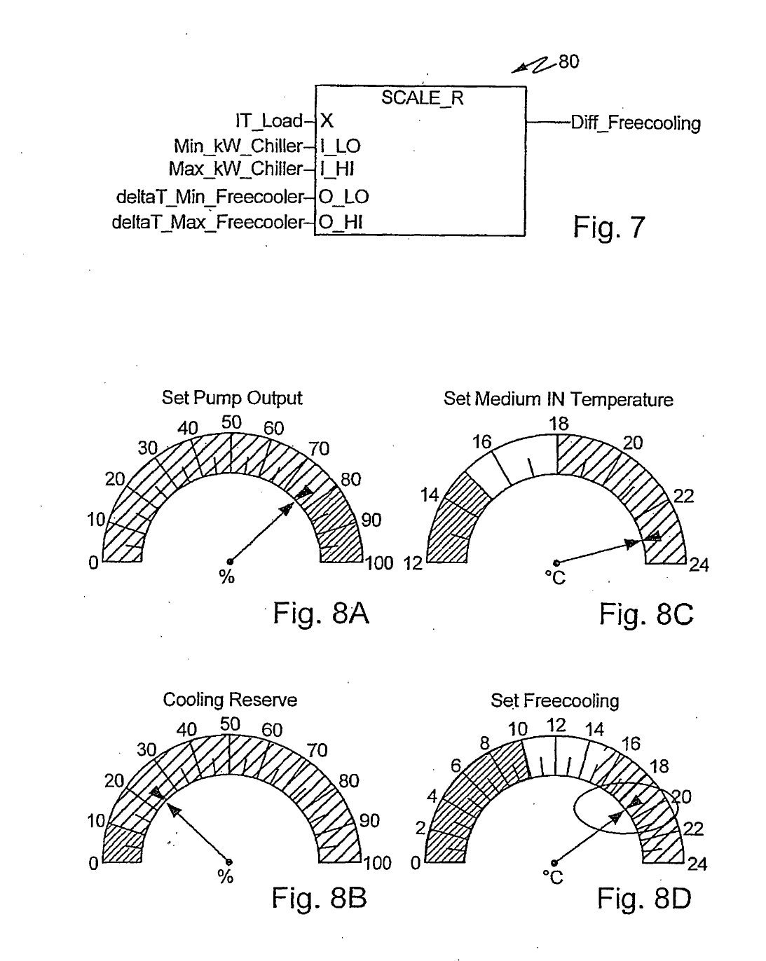

FIG. 7 a control part of the cooling system taking into account the operation of a free-cooler,

FIG. 8 different scales with displayed scale values,

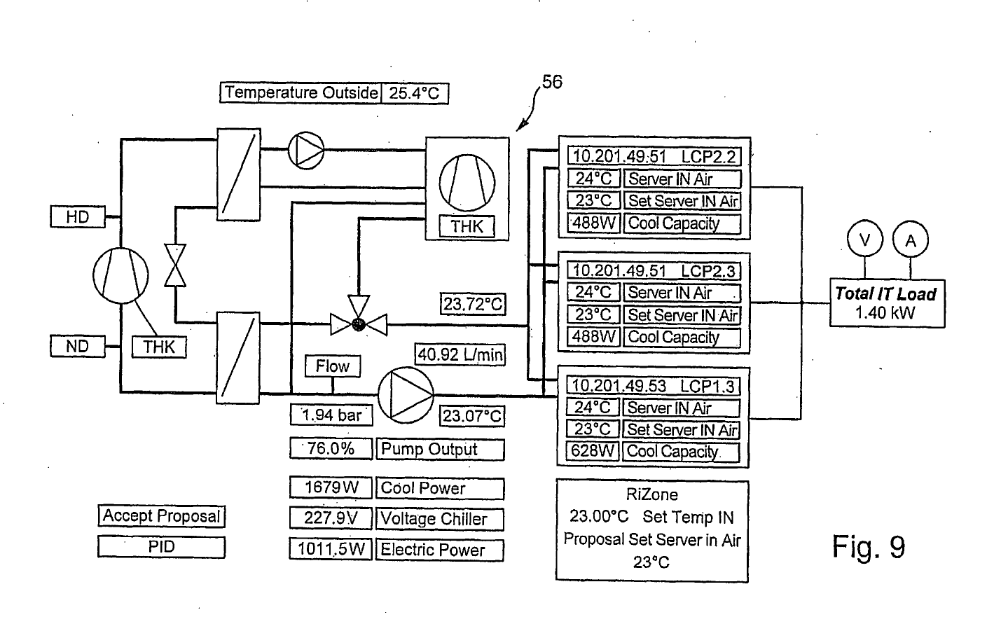

FIG. 9 a further graphic illustration of the cooling system by means of the display,

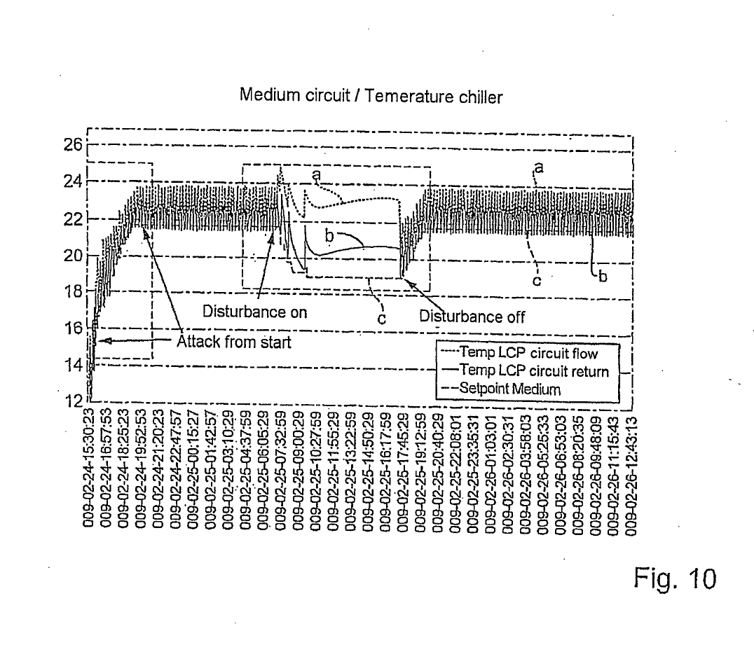

FIG. 10 temperature profiles of a flow temperature and a return temperature as well as pre-set values of the cooling medium versus time, and

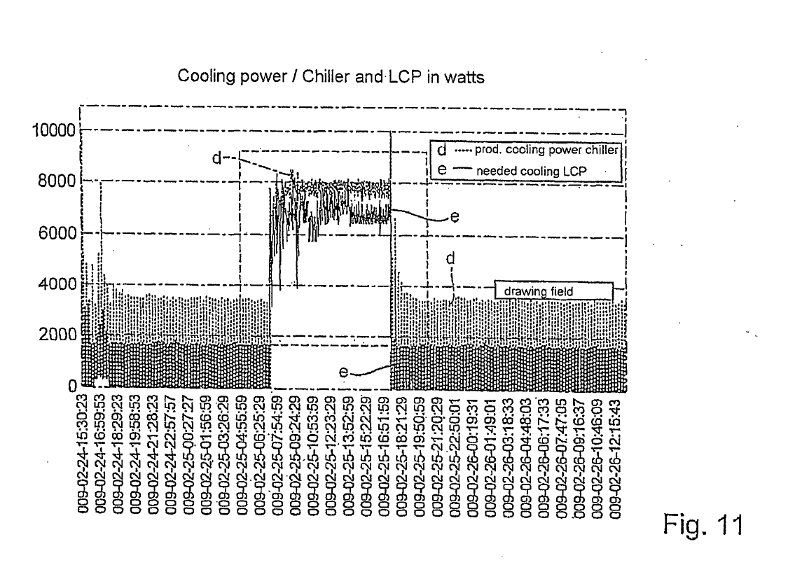

FIG. 11 profiles of a cooling power produced by the back-flow cooling apparatus and a cooling power required in the cooling units versus time.

FIG. 1 shows schematically as essential components of a cooling system for cooling electrical built-in devices, such as e.g. servers, housed in control cabinets or racks, a cooling apparatus 10 arranged in the region of built-in devices having plural, presently a first, a second and a third cooling unit 11, 12, 13, a back-flow cooling apparatus 20 for a fluid, in particular liquid cooling medium, such as e.g. water, as well as a free-cooling device 30 by which the cooling medium additionally or at times even completely by using ambient air may be cooled down to provide a requisite cooling power for safe operation of the built-in devices in the region of the built-in devices via cooling units 11, 12, 13. Cooling units 11, 12, 13 may be associated to the built-in devices 1:1 or one cooling unit may be associated to several built-in devices and may comprise identical or different cooling powers and/or identical or different temperature set values, for example supply temperature values, wherein cooling powers and temperature values may be predefined. The flow temperature of the cooling medium supplied to cooling units 11, 12, 13 is adaptively adjusted according to the required cooling power in the region of the built-in devices, wherein by means of free-cooling device 30 cooling is supported within the realm of the usable cooling power from ambient air and an adaptive adjustment of the cooling power supplied from free-cooling devices 30 also occurs within this realm.

FIG. 2 shows two representations generated via a display 50 for two different operating states of the cooling system, wherein alphanumeric information is offered via an alphanumeric part 51 and graphic information via a graphic part 52 of display 50. This representation results in a operator friendly user guidance and will below serve to explain the arrangement and the regulation method in detail.

In contrast to prior methods for regulating cooling system for electrical built-in devices housed in control cabinets or racks which are self-sustaining with fixed parameters and, in that context, require provisioning of cooling power which is in some respects unnecessary, the flow temperature, in the present regulation method, is adapted according to a cooling power requirement in the region of the built-in devices, and the primary reference value is determined from the cooling power demand in the region of the built-in devices. In the exemplary embodiment, cooling units 11, 12, 13, through which cooling medium flows, are equipped with fans which, in the region of the built-in devices, for example in a 19″ installation level, produce supply air required for cooling, wherein the supply air temperature is maintained on a predefined level by the cooling system. The pre-set temperatures in the different components of the cooling system, in particular for flow temperature of the back-flow cooling apparatus 20 and a further pre-set temperature in the optionally present free-cooling device 30, are adaptively adjusted to the cooling power demand in the region of the built-in devices, in the present exemplary embodiment therefore to the supply air temperature in the region of the built-in devices. Thus, the water flow temperature as well as the further pre-set value of the free-cooling device 30, in the following referred to as free-cooling pre-set value, are determined by the actual cooling power demand.

FIG. 2 shows in its left-hand illustration an operating condition at low outside temperature (e.g. 2.8° C.), where free-cooling device is effectively usable, as emphasized by operating modus F, free-cooling F1. As further indications, flow temperature A of back-flow cooling apparatus 20, return temperature B, flow rate C, pressure of cooling medium D, cooling capacity or cooling power, respectively, E, a pre-set value of the cooling medium or pre-set value of the flow temperature G in the region of the back-flow cooling apparatus 20, free-cooling pre-set value H, outside temperature I as well as electrical power values J, K, L are represented on the alphanumeric part 51, and further, as overall information, power consumed by built-in devices M, CO₂ production N, costs per hour 0 and an efficiency factor P are displayed. Some of these indications with a respective designation are also found in the graphic part, wherein “freecooling” refers to free-cooling device 30 and “chiller” refers to back-flow cooling apparatus 20.

In the right-hand illustration of FIG. 2, altered parameters or measured values, respectively, are present for the previously mentioned designations, wherein as operating mode F the operation of back-flow cooling apparatus F2 is displayed. It results from the comparison of both illustrations that operation of the cooling system and regulation adaptively adjust to present physical facts.

FIG. 3 shows an installation example comprising the cooling system, wherein additionally to the back-flow cooling apparatus 20 and two cooling units 11, 12 pumps 40, a buffer tank 41 for cooling medium, filters 45, manifolds 46 as well as a UKS arrangement 60 having several UKS devices 61, 62, 63 are shown as further components of the cooling system. That arrangement with cooling system may be operated according to the presently described regulation method, wherein by means of pumps 40 the supplied volume of cooling medium per time unit can be controlled quickly according to the cooling power demand.

FIG. 4 shows an illustration of the arrangement and of operation procedures with measured values and parameters in the region of the cooling units (LCP) 11, 12, 13 by display 50 having alphanumeric part 51 and graphic part 52. Individual components of the cooling system, such as fans, pumps, heat exchangers, compressor, are marked by usual symbols and are known per se. Cooling units 11, 12, 13 are represented in cooling unit displays 53, 54, 55 and also in a combination in a functional representation 56 in which also a display area for a superordinate device status display 47 is represented which is obtained from a superordinate control platform (RiZone) and e.g. includes parameter and measured values from electrical consumers. FIG. 4 illustrates the arrangement and the regulation method.

The predefined or produced supply air temperature values of all cooling units 11, 12, 13 are compared to determine the smallest supply air temperature value, wherein also several identical supply air temperature values of the cooling units may be present. The supply air temperature is based on the smallest supply air temperature value, thus determining the primary reference value. The supply air temperature value directly influences the pre-set value of the water flow temperature which is to be calculated and accordingly adaptively adjusted.

Each cooling unit 11, 12, 13 which set point (pre-set value of the cooling unit) has been determined to be active is considered as a control system. Thereafter, comparison of the temperature difference between pre-set value and actual value of each cooling unit is made. The currently largest control deviation is derived therefrom which then forms the basis as a control deviation for the regulation, wherein preferably a PID control is performed. Concurrently, when applying a PID control, the D part of the control deviation is considered, an if the temporal variation exceeds a predetermined threshold, the flow temperature is again adjusted. Thereby, an optionally present gradient deviation alarm can be used.

To achieve at an efficient control of the provided cooling power which is best possible adapted to equipment and physical facts, all, if possible, detected measured values are centrally collected. Advantageously, a central control unit 70 is provided, as shown in FIG. 5. In particular, also driving of the pump for controlling the pumping power is taken into account. A total demand of cooling power or cooling energy, respectively, is determined from the cooling power demand or energy demand, respectively, of the individual cooling units 11, 12, 13. A necessary reserve of the pump(s) is calculated therefrom in order to be able to quickly react to a varying load demand of electrical consumers or an increased cooling power demand associated therewith in a short time. Simultaneously, an adaption of the flow temperature by decreasing is started, the effect thereof being delayed due to idleness. FIG. 6 shows exemplarily a time profile of pumping power of the back-flow cooling device 20.

The free-cooling pre-set value is calculated from the pre-set value of the flow temperature of the cooling medium minus a known temperature difference of the free-cooling device 30. Then, an adaptive adjustment occurs by measuring the actual power loss of the electrical built-in components, such as e.g. the servers, under simultaneously consideration (scaling) of the temperature difference of the free-cooling device 30. A control part 80 for adaptively adjusting the free-cooling pre-set value is illustrated in FIG. 7.

Since the control is performed with regard to the actual cooling power demand or the respective energy demand, in individual cases a free-cooling pre-set value which is strongly increased by the control apparatus may result. Increasing the free-cooling pre-set value leads to more possible provision of cooling power by free-cooling device 30. This results in a more efficient use of energy, since cooling by means of a free-cooling device needs only about 10 to 20% of the electrical energy of the back-flow cooling apparatus 20.

FIG. 8 shows different scales with scale values indicated by pointers, namely pump output power 8A in percentages, a cooling reserve 8B, a set point of the cooling medium input temperature 8C and a set point of the free-cooling temperature (free cooling pre-set value) 8D.

In FIG. 9, the arrangement of a control apparatus similar to the left hand lower partial representation of FIG. 4 is illustrated in more details, so that also the regulation method is illustrated.

FIG. 10 shows temperature profiles of a flow temperature (a), a return temperature (b) and a pre-set value of the flow temperature in the region of the back-flow cooling apparatus 20. From the beginning, the pre-set value of the flow temperature is adjusted in steps during an attack, until a stationary value is reached. Also, in the range of occurrence of a disturbance (disturbance ON to disturbance OFF), the pre-set value of the flow temperature is adaptively adjusted (c).

FIG. 11 shows profiles of a cooling power (d) produced with the back-flow cooling apparatus and cooling power (e) needed in the cooling units versus time. Cooling power (d) produced by back-flow cooling apparatus 20 is adjusted according to the needed cooling power (e) as shown in particular also during a strongly varying required cooling power.

With the aid of the measures of regulation of the cooling power or supply air temperature, respectively, as described, a load-dependent cooling air flow is provided to the built-in devices or servers, respectively, directly at the device. Thus, a control across the system towards a server supply air temperature is realized, e.g. in a completely implemented IT cold chain. The IT cold chain thereby includes for example in the server room devices which are for air-conditioning of a server rack, such as e.g. the cooling units (LCP=Liquid Cooling Packages) as previously described, devices which are for air-conditioning the room, such as e.g. UKS devices, and devices which are for air-conditioning a cabinet row (e.g. cooling units and UKS devices). Outside the server racks or server cabinets, respectively, the IT cold chain may include devices which provide liquid cooling medium, in particular cooling water, such as e.g. back-flow cooling apparatus or devices using cold earth or cold absorption, as well as devices which support the back-flow apparatus energy-efficiently, such as e.g. the free-cooling device. In the periphery of the IT cold chain aisle separations which separate server supply air and server exhaust air, pipes connecting e.g. cold water generators and cold water consumers and pumps providing the cooling medium according to performance, may be provided. By using a main control apparatus, e.g. having the central control unit 70 to which all system relevant parameters which essentially determine the energy efficiency of the air conditioning are provided, all devices are controlled such that cooling power demand or server supply air temperature, respectively, is kept at the level desired by the user. This level may be varied dynamically according to the system condition. The regulation method having the regulation algorithm takes into consideration that all devices involved are operated in an energetically most favourable operating condition, in particular using small air volumes, small flows, pre-cooling proportion as high as possible. The system as a whole thereby is optimized according to the actual energy demand.

1-14. (canceled)

15. A method for regulating a cooling system for cooling electrical built-in devices housed in control cabinets or racks by means of cooling units assigned thereto, through which a liquid cooling medium, cooled down from a return temperature to a flow temperature by means of a cooling apparatus of the cooling system flows, wherein a cooling power for cooling the built-in devices can be regulated by a primary reference variable according to specification, wherein the flow temperature is variably adjusted according to a cooling power demand in the region of the built-in devices, and wherein the primary reference variable is derived from the cooling power demand in the region of the built-in devices.

16. The regulation method of claim 15, wherein said cooling apparatus comprises a back-flow cooling apparatus for cooling the cooling medium at least partly and/or at least temporarily.

17. The regulation method of claim 16, wherein the primary reference variable is determined from a supply air temperature of supply air in the region of the built-in devices, wherein the supply air temperature is maintained at a predefined level according to the primary reference variable by the cooling system.

18. The regulation method of claim 16, wherein the cooling system comprises several cooling units having fans which produce the supply air and that the predefined or produced supply air temperature values of all cooling units are compared to determine the smallest or, optionally, the same value, and the supply temperature is based on the smallest supply air temperature value, thus determining the primary reference value and adjusting the water flow temperature.

19. The regulation method of claim 18, wherein within the controlled system each cooling unit is seen as having an active pre-set value, that a comparison of the temperature difference between pre-set value and actual value of each cooling unit is made and that a control deviation for control is derived from the presently largest temperature difference of the cooling units.

20. The regulation method of claim 15, wherein a PID control is performed.

21. The regulation method of claim 20, wherein a temporal variation of the control deviation is considered as D part of the control deviation, and, if the temporal variation exceeds a pre-defined threshold, the flow temperature is adjusted.

22. The regulation method of claim 15, wherein the flow temperature is adjusted by altering a pre-set value of the flow temperature and the flow temperature is adjusted to the altered pre-set value of the flow temperature.

23. The regulation method of claim 15, wherein cooling of the cooling medium is provided at least temporarily, partly or completely by means of a free-cooling device or an earth cooling device or an absorption cooling device.

24. The regulation method of claim 23, wherein a free-cooling pre-set value is calculated from the pre-set value of the flow temperature minus a known temperature difference of the free-cooling device.

25. The regulation method of claim 24, wherein the free-cooling pre-set value is adaptively adjusted in response to cooling requirements.

26. The regulation method of claim 15, wherein the primary reference value is determined according to a most energy-efficient cooling possible of the built-in devices, wherein the power dissipation of the built-in devices in the range of allowable operating temperatures is calculated in accordance with a most energy-efficient operation possible of the system as a whole, including the cooling system.

27. The regulation method of claim 26, wherein the built-in devices comprise servers.

28. An arrangement comprising a cooling system for cooling electrical built-in devices housed in control cabinets or racks, at least one cooling unit assigned to the built-in devices, through which a cooling medium flows, a reverse cooling apparatus for cooling down the cooling medium and a control apparatus for performing the regulation method according to claim 15.

29. The arrangement of claim 28, wherein a free-cooling device is further provided and the control apparatus is further for performing the method wherein the flow temperature is adjusted by altering a pre-set value of the flow temperature and the flow temperature is adjusted to the altered pre-set value of the flow temperature.
